(19) United States
(12) Patent Application Publication
(10) Pub. No.: US 2025/0305126 A1
(43) Pub. Date: Oct. 2, 2025

(54) PARTICLE COATING APPARATUS AND PARTICLE COATING METHOD

(71) Applicant: SEIKO EPSON CORPORATION, TOKYO (JP)

(72) Inventor: Ryujiro SAIBA, MATSUMOTO-SHI (JP)

(21) Appl. No.: 19/090,870

(22) Filed: Mar. 26, 2025

(30) Foreign Application Priority Data
Mar. 26, 2024 (JP) 2024-049148

(51) Int. Cl. C23C 16/44; B22F 1/142; B22F 1/145; C23C 16/02; C23C 16/455; C23C 16/458; H01F 1/20

(52) U.S. Cl. CPC C23C 16/4417; B22F 1/142; B22F 1/145; C23C 16/0209; C23C 16/45544; C23C 16/45555; C23C 16/458; H01F 1/20; B22F 2304/10; B22F 2998/10

(57) ABSTRACT

A particle coating apparatus 1 includes: a chamber 11 having a volume of 10 L to 100 L; a gas introduction unit 16 provided at the chamber 11 and configured to introduce a predetermined gas into the chamber 11; a gas discharge unit 18 provided at the chamber 11 and configured to discharge the gas in the chamber 11; a heating unit 15 configured to heat an inside of the chamber 11; a plurality of trays 12 accommodated in the chamber 11 and configured to hold metal particles 31 and form a powder layer 30 at a predetermined depth; and a valve 21 coupled to the gas introduction unit 16 and a valve 23 provided at the gas discharge unit 18. The plurality of trays 12 are stacked at a gap of 5 mm or more and 200 mm or less, and a conductance between the trays 12 in an atmosphere at 20° C. is 20 m³/s to 2.0×10⁴ m³/s.

The present application is based on, and claims priority from JP Application Serial Number 2024-049148, filed Mar. 26, 2024, the disclosure of which is hereby incorporated by reference herein in its entirety.

### BACKGROUND

### 1. Technical Field

The present disclosure relates to a particle coating apparatus and a particle coating method.

### 2. Related Art

In a magnetic powder used for an inductor or the like, it is necessary to perform an insulating treatment on surfaces of particles to prevent an eddy current flowing between the particles or insulate the particles from each other. Therefore, a method of forming an insulating film on the surfaces of the particles of the magnetic powder using various film formation methods has been studied. For example, JP-A-2021-085050 discloses a particle coating apparatus that forms an insulating film on a surface of a soft magnetic metal particle by an atomic layer deposition (ALD) method, which is one type of a chemical vapor deposition method. According to the atomic layer deposition method, an insulating film that is small and uniform in film thickness can be formed.

However, in the particle coating apparatus described in JP-A-2021-085050, soft magnetic metal particles are put into a tray to form an insulating film, but in order to form a film with a uniform film thickness, it is necessary to limit the amount of soft magnetic metal particles put into the tray. Therefore, the particle coating apparatus described in JP-A-2021-085050 has a problem that the production efficiency of the particles with insulating films cannot be sufficiently increased.

### SUMMARY

A particle coating apparatus includes: a chamber having a volume of 10 L to 100 L; a gas introduction unit provided at the chamber and configured to introduce a predetermined gas into the chamber; a gas discharge unit provided at the chamber and configured to discharge the gas in the chamber; a heating unit configured to heat an inside of the chamber; a plurality of trays accommodated in the chamber and configured to hold metal particles to form a powder layer at a predetermined depth; and a valve coupled to the gas introduction unit and a valve provided at the gas discharge unit. The plurality of trays are stacked at a gap of 5 mm or more and 200 mm or less, and a conductance between the trays in an atmosphere at 20° C. is 20 m³/s to 2.0×10⁴ m³/s.

A particle coating method includes: an arrangement step of stacking, at a gap of 5 mm or more and 200 mm or less, a plurality of trays configured to hold metal particles to form a powder layer at a predetermined depth and accommodating and arranging the plurality of trays in a chamber; a heating step of heating the powder layer in a temperature range of 100° C. or higher and 500° C. or lower for 0.1 hours or longer and 300 hours or shorter; and an insulating film forming step of forming an insulating film on surfaces of the metal particles by an atomic layer deposition method. In the insulating film forming step, a conductance between the trays in an atmosphere at 20° C. is 20 m³/s to 2.0×10⁴ m³/s.

### BRIEF DESCRIPTION OF THE DRAWINGS

FIG. 1 is a schematic cross-sectional view illustrating an example of a particle coating apparatus according to an embodiment.

FIG. 2 is a schematic cross-sectional view illustrating tray holding metal particles and an interval between stacked trays.

FIG. 3 is a diagram illustrating a method of introducing a gas depending on an average particle diameter of metal particles.

FIG. 4 is a diagram illustrating a method of introducing a gas depending on an average particle diameter of metal particles.

FIG. 5 is a cross-sectional view schematically illustrating a particle with an insulating film produced by the particle coating apparatus according to the embodiment.

FIG. 6 is a flowchart illustrating a particle coating method according to the embodiment.

### DESCRIPTION OF EMBODIMENTS

### 1. Particle Coating Apparatus

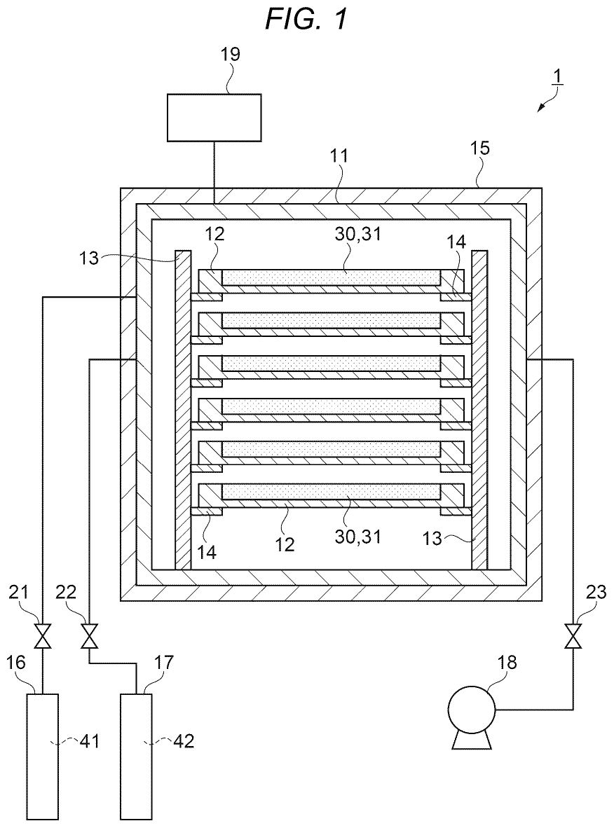

First, a particle coating apparatus 1 according to the embodiment will be described with reference to FIGS. 1 to 5.

As illustrated in FIG. 1, the particle coating apparatus 1 according to the embodiment includes a chamber 11, a tray 12, placement parts 14, a heating unit 15, a gas introduction unit 16, an oxidant introduction unit 17, a gas discharge unit 18, and valves 21, 22, and 23.

In the particle coating apparatus 1, after metal particles 31 are accommodated in the chamber 11 and an inside of the chamber 11 is exhausted by the gas discharge unit 18, a gas 41 and an oxidant 42 are respectively introduced from the gas introduction unit 16 and the oxidant introduction unit 17. Further, the metal particles 31 are heated by the heating unit 15. The gas 41 introduced into the chamber 11 is decomposed, and a decomposition product is adsorbed on a surface of the metal particle 31, and thus an insulating film 32 illustrated in FIG. 5 is finally formed. Accordingly, a particle 33 with an insulating film illustrated in FIG. 5 is obtained.

The chamber 11 is a container having rigidity and airtightness and has a volume of 10 L to 100 L. In a state in which the metal particles 31 are accommodated in the chamber 11, the insulating film 32 is formed at the surface of the metal particle 31. The chamber 11 is maintained at a reduced pressure state by exhausting the inside. Examples of constituent materials of the chamber 11 include a glass material such as quartz glass, a ceramic material such as alumina, and a metal material such as stainless steel, aluminum, or titanium. Further, an inner wall of the chamber 11 has a surface roughness Ra of 0.1 or less so that the gas 41 and the oxidant 42 are not adsorbed to the inner wall. Alternatively, a material of the inner wall is gold or ruthenium so that the gas 41 and the oxidant 42 are not adsorbed to the inner wall. Alternatively, the inner wall is coated with fluorine so that the gas 41 and the oxidant 42 are not adsorbed to the inner wall.

The gas introduction unit 16 and the oxidant introduction unit 17 are coupled to the chamber 11. The gas introduction unit 16 supplies the gas 41 necessary for forming the insulating film 32 into the chamber 11 by opening and closing the valve 21 provided at a pipe between the gas introduction unit 16 and the chamber 11, and adjusts a partial pressure of the gas 41 in the chamber 11. The oxidant introduction unit 17 supplies the oxidant 42 necessary for forming the insulating film 32 into the chamber 11 by opening and closing the valve 22 provided at a pipe between the oxidant introduction unit 17 and the chamber 11, and adjusts a partial pressure of the oxidant 42 in the chamber 11. Examples of the oxidant 42 include ozone, plasma oxygen, and water vapor. By using ozone as the oxidant 42, it is possible to more efficiently form the insulating film 32 which is denser and is uniform in film thickness. The gas 41 and the oxidant 42 are supplied together with a carrier gas containing an inert gas such as nitrogen gas or argon gas as a main component as necessary.

The gas discharge unit 18 exhausts the inside of the chamber 11 by opening and closing the valve 23 provided at a pipe between the gas discharge unit 18 and the chamber 11. Accordingly, the inside of the chamber 11 can be depressurized. The gas discharge unit 18 is, for example, a vacuum pump. The pressure in the chamber 11 is measured by a vacuum gauge 19.

The heating unit 15 heats chamber 11 and accordingly heats a powder layer 30. Examples of the heating unit 15 include a heater block, a film heater, a sheet heater, a seeds heater, and an infrared radiation heater. In FIG. 1, the heating unit 15 is disposed outside the chamber 11, but the arrangement of the heating unit 15 is not limited thereto. For example, the heating unit 15 may be disposed inside the chamber 11, or may be incorporated in a wall body constituting the chamber 11. The heating unit 15 may be provided as necessary, or may be omitted.

By providing the heating unit 15, the temperature of the powder layer 30 and the temperatures of the gas 41 and the oxidant 42 can be optimized. Accordingly, it is possible to more efficiently form the insulating film 32 which is denser and is uniform in film thickness.

The chamber 11 has an opening/closing unit (not illustrated), and the tray 12 holding the powder layer 30 of the metal particles 31 is carried into and out of the chamber 11 from the opening/closing unit.

Leg parts 13 and the placement parts 14 are provided in the chamber 11. The leg part 13 extends upward from a bottom surface in the chamber 11. A plurality of leg parts 13 are arranged on the bottom surface at predetermined intervals. The plurality of placement parts 14 arranged at predetermined intervals are attached to the leg part 13. Each of the placement parts 14 is configured to support the tray 12 from below. Accordingly, a plurality of trays 12 is detachably supported by the plurality of placement parts 14. The configuration of the leg parts 13 and the placement parts 14 is not limited to the illustrated configuration as long as the trays 12 can be supported in the configuration. Further, the number of the placement parts 14 is not particularly limited as long as it is plural, and is appropriately set according to, for example, the size of the chamber 11 and the size of the tray 12.

The plurality of trays 12 are arranged in a stacked manner in the chamber 11. The trays 12 each hold the metal particles 31 in the form of the powder layer 30 in which the metal particles 31 are laid in a layer. The holding means maintaining the relative positions of the metal particles 31 so that the relative positions do not change, and specifically means that the powder layer 30 is left at rest. By arranging the plurality of trays 12 in a stacked manner, the plurality of trays 12 can be arranged in a space-saving manner, and a large number of metal particles 31 can be provided for forming an insulating film one time. Accordingly, it is possible to improve the production efficiency of the particles 33 with the insulating film while saving the space of the particle coating apparatus 1.

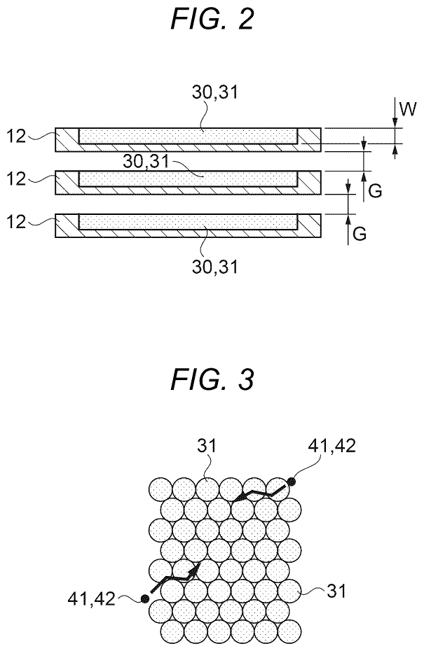

As illustrated in FIG. 2, the trays 12 are arranged in a stacked manner such that a gap G between a tray 12 and another tray 12 is 5 mm or more and 200 mm or less. The conductance that is piping resistance between the trays 12 in an atmosphere at 20° C. is 20 m³/s to 2.0×10⁴ m³/s. Accordingly, the gas 41 and the oxidant 42 easily enter the gap between the trays 12, and the insulating film 32 is easily formed at a uniform film thickness.

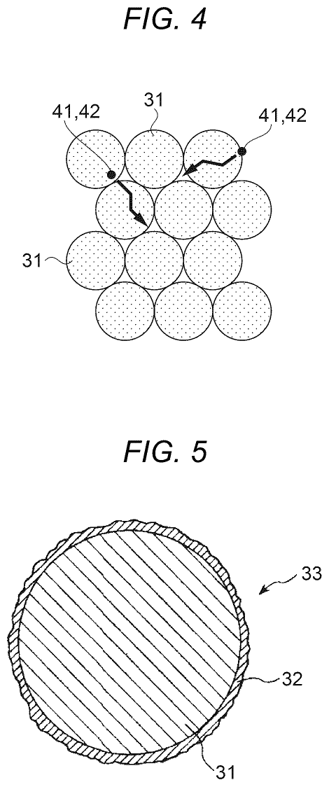

A depth W of the tray 12 varies depending on the average particle diameter of the metal particles 31. When the average particle diameter of the metal particles 31 is 0.5 μm to 10 μm, the depth W of the tray 12 is 5 mm or less, and when the average particle diameter of the metal particles 31 is 10 μm to 100 μm, the depth W of the tray 12 is 10 mm or less. When the average particle diameter of the metal particles 31 is small, the gap between the metal particles 31 are narrow as shown in FIG. 3, and therefore, the gas 41 and the oxidant 42 hardly enter the gap between the metal particles 31. In contrast, when the average particle diameter of the metal particles 31 is large, the gap between the metal particles 31 is wide as shown in FIG. 4, and therefore, the gas 41 and the oxidant 42 easily enter the gap between the metal particles 31. Therefore, when the average particle diameter of the metal particles 31 is large, the depth W of the tray 12 can be increased because the gas 41 and the oxidant 42 can easily enter the gap between the metal particles 31 even if the powder layer 30 is made thick, as compared with the case where the average particle diameter of the metal particles 31 is small. Accordingly, even when the average particle diameter of the metal particles 31 is large, the production efficiency of the particles 33 with the insulating film can be increased.

The constituent material of the tray 12 is not particularly limited, and examples thereof include a metal material, a resin material, a ceramic material, a glass material, and a carbon material. The constituent material of the tray 12 may be a composite material containing two or more of these materials. An inner surface of the tray 12 has a surface roughness Ra of 0.1 or less so that the gas 41 and the oxidant 42 are not adsorbed to the inner surface. Alternatively, a material of the inner surface is gold or ruthenium so that the gas 41 and the oxidant 42 are not adsorbed to the inner surface. Alternatively, the inner surface is coated with fluorine so that the gas 41 and the oxidant 42 are not adsorbed to the inner surface.

Next, the particle 33 with an insulating film produced by the particle coating apparatus 1 according to the embodiment will be described.

As illustrated in FIG. 5, the particle 33 with an insulating film is one particle of the treated powder and contains the metal particle 31 and the insulating film 32.

A constituent material of the metal particles 31 is, for example, a soft magnetic metal material. When the metal particles 31 made of the soft magnetic metal material are used in a magnetic component such as an inductor, it is necessary to ensure insulation between the metal particles 31. By using the particle coating apparatus 1 described above, it is possible to form the insulating film 32 having a sufficiently small film thickness and a high coverage. Accordingly, the particles 33 with the insulating film capable of enhancing the magnetic properties and the insulating properties of the magnetic component are obtained. In addition, the insulating film 32 formed by the atomic layer deposition method is dense, and therefore, the insulating film 32 also contributes to, for example, implementation of the particles 33 with the insulating film which have high insulating properties.

Examples of the soft magnetic metal material include pure iron, various Fe-based alloys such as an Fe—Si-based alloy such as silicon steel, an Fe—Ni-based alloy such as permalloy, an Fe—Co-based alloy such as permendur, an Fe—Si—Al-based alloy such as sendust, and an Fe—Cr—Si-based alloy, various Ni-based alloys, various Co-based alloys, and various amorphous alloys. Among these, examples of the amorphous alloys include Fe-based alloys such as Fe—Si—B-based, Fe—Si—B—C-based, Fe—Si—B—Cr—C-based, Fe—Si—Cr-based, Fe—B-based, Fe—P—C-based, Fe—Co—Si—B-based, Fe—Si—B—Nb-based, and Fe—Zr—B-based alloys, Ni-based alloys such as Ni—Si—B-based and Ni—P—B-based alloys, and Co-based alloys such as Co—Si—B-based alloys.

The constituent material of the insulating film 32 is an oxide such as silicon oxide, hafnium oxide, tantalum oxide, titanium oxide, or chromium oxide.

As described above, in the particle coating apparatus 1 according to the embodiment, the plurality of trays 12 in which the powder layer 30 of the metal particles 31 is formed are stacked at a gap G of 5 mm or more and 200 mm or less, and are accommodated and arranged in the chamber 11, and therefore, the gas 41 and the oxidant 42 can easily enter the gap between the trays 12, and the insulating film 32 can be easily formed at a uniform film thickness. In addition, the plurality of trays 12 are stacked, and therefore, it is possible to efficiently produce the particles 33 with the insulating films while saving the space of the particle coating apparatus 1.

The conductance between the trays 12 in an atmosphere at 20° C. is 20 m³/s to 2.0×10⁴ m³/s, and therefore, the gas 41 and the oxidant 42 easily enter the gap between the trays 12, and the insulating film 32 is easily formed at a more uniform film thickness.

### 2. Particle Coating Method

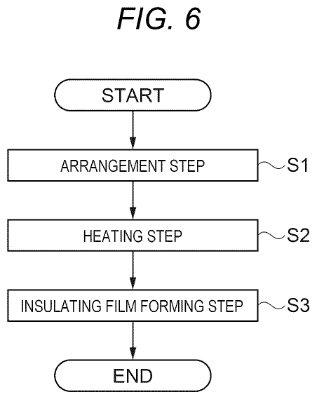

Next, a method of forming the insulating film 32 on the surface of the metal particle 31 using the particle coating apparatus 1 shown in FIG. 1 as the particle coating method according to the embodiment will be described with reference to FIG. 6.

As shown in FIG. 6, the particle coating method includes an arrangement step S1, a heating step S2, and an insulating film forming step S3.

### 2.1. Arrangement Step S1

First, a plurality of trays 12 for holding the metal particles 31 to form the powder layer 30 at a predetermined depth W are stacked at a gap G of 5 mm or more and 200 mm or less, and are accommodated and arranged in the chamber 11. By setting the gap G between the trays 12 to 5 mm or more and 200 mm or less, the gas 41 and the oxidant 42 easily enter the gap G between the trays 12 in the insulating film forming step S3 described below, and the insulating film 32 is easily formed at a uniform film thickness.

When the average particle diameter of the metal particles 31 is 0.5 μm to 10 μm, the powder layer 30 is formed on the tray 12 having a depth W of 5 mm or less. When the average particle diameter of the metal particles 31 is 10 μm to 100 μm, the powder layer 30 is formed on the tray 12 having a depth W of 10 mm or less.

### 2.2. Heating Step S2

Next, the inside of the chamber 11 is exhausted by the gas discharge unit 18. Accordingly, the inside of the chamber 11 is depressurized.

Next, a pretreatment is performed on the metal particles 31 charged into the chamber 11, as necessary. Examples of the pretreatment include an ozone treatment, a radical treatment, an ultraviolet radiation treatment, a plasma treatment, a corona treatment, a drying treatment, and a solvent treatment. The pretreatment may be performed after the heating treatment described below.

Next, the metal particles 31 charged into the chamber

11 are heated. This heating may be performed temporally overlapping the film formation of the insulating film 32 described below, or may be performed separately from the film formation, that is, without temporally overlapping the film formation. That is, at least a part of the heating step S2 and the insulating film forming step S3 described below may be performed in the same time period or may be performed in different time periods.

The heating temperature is 100°° C. or higher and 500° C. or lower, preferably 150° C. or higher and 450° C. or lower, and more preferably 200° C. or higher and 400° C. or lower. The heating time at such a heating temperature is 0.1 hours or longer and 300 hours or shorter, and is appropriately set according to the heating temperature, preferably 0.5 hours or longer and 50 hours or shorter, and more preferably 1 hour or longer and 40 hours or shorter.

A strain contained in the metal particles 31 can be reduced by performing the heating under such heating conditions. The strain refers to a stress strain caused by pulverization, a thermal strain caused by cooling, or the like when the metal particles 31 are produced. It is possible to prevent crystallization of an amorphous phase contained in the metal particles 31 and reduce strain by performing heating under the above-described heating conditions. As a result, in the metal particles 31, excellent low coercive force and low eddy current loss derived from the amorphous phase are maintained, and a further reduction in coercive force is achieved along with the relaxation of strain.

The heating time described above refers to a cumulative time during which the metal particles 31 stay within the heating temperature range described above. Therefore, the metal particles 31 do not need to remain continuously within the heating temperature range described above, but from the viewpoint of easy relaxation of strain, the metal particles 31 preferably remain continuously.

A product of the heating temperature and the heating time is preferably 500 [° C.·hour] or more and 10000 [° C.·hour] or less, and more preferably 1000 [° C.·hour] or more and 9000 [° C.·hour] or less. Accordingly, the heating can be performed for a relatively long time, and therefore, the heating temperature can be lowered, and the strain of the metal particles 31 can be sufficiently relaxed while preventing the crystallization of the amorphous phase. When the heating step S2 and the insulating film forming step S3 are performed in the same time period, the thickness of the insulating film 32 can be optimized.

That is, when the product of the heating temperature and the heating time is less than the lower limit value, the strain of the metal particles 31 may not be sufficiently relaxed, or the thickness of the insulating film 32 may be insufficient. On the other hand, when the product of the heating temperature and the heating time exceeds the upper limit value, the amorphous phase may be crystallized or the thickness of the insulating film 32 may become too large depending on the heating temperature.

The product of the heating temperature and the heating time is determined as a time integral value of the heating temperature. The pressure in the chamber 11 during the heating is preferably, for example, 100 Pa or less. It is possible to prevent oxidation of the metal particles 31 and to prevent an increase in coercive force due to oxidation by performing heating under such reduced pressure.

### 2.3. Insulating Film Forming Step S3

In this step, the insulating film 32 is formed on the surfaces of the metal particle 31.

Specifically, first, in a state in which the inside of the chamber 11 is completely sealed, the gas 41 is introduced into the chamber 11 from the gas introduction unit 16 under a condition that the conductance which is piping resistance between the trays 12 in an atmosphere at 20° C. is 20 m³/s to 2.0×10⁴ m³/s. The introduced gas 41 is adsorbed to the surfaces of the metal particles 31. On this occasion, when the gas 41 is adsorbed to the surfaces of the metal particles 31, the gas 41 is less likely to be further adsorbed to other layers. Therefore, the thickness of the insulating film 32 finally obtained can be controlled with high accuracy. In addition, the gas 41 also goes around and adsorbs to a shaded portion or a gap portion of the metal particles 31, and therefore, the thickness of the insulating film 32 is made uniform.

Examples of the gas 41 include a gas containing a precursor of the insulating film 32. When the silicon-based insulating film 32 is formed, specific examples of the gas 41 include secondary amines such as dimethylamine, methylethylamine, and diethylamine, and reaction products of secondary amines and trihalosilanes, such as tris(dimethylamino)silane, bis(diethylamino)silane, and bis(tertiary-butylamino)silane.

Next, after the gas 41 in the chamber 11 is discharged by the gas discharge unit 18, an inert gas such as nitrogen gas or argon gas is introduced as necessary. Accordingly, the gas 41 is replaced. Introduction of the inert gas can be performed by the same method as that of introduction of the gas 41 and the oxidant 42, although not shown.

Next, after the inert gas in the chamber 11 is discharged by the gas discharge unit 18, the oxidant 42 is introduced into the chamber 11 from the oxidant introduction unit 17 under a condition that the conductance which is piping resistance between the trays 12 in an atmosphere at 20° C. is 20 m³/s to 2.0×10⁴ m³/s. Examples of the oxidant 42 include ozone, plasma oxygen, and water vapor.

The oxidant 42 reacts with the gas 41 adsorbed to the surface of the metal particle 31 to form the insulating film 32. Similarly to the gas 41, the oxidant 42 also goes around a shaded portion or a gap portion of the metal particles 31, so that the thickness of the insulating film 32 can be controlled uniformly with high accuracy.

Next, after the oxidant 42 in the chamber 11 is discharged from the gas discharge unit 18, an inert gas is introduced as necessary to replace the oxidant 42. As described above, the insulating film 32 is formed, and the particles 33 with the insulating films are obtained.

The introduction and discharge of the gas 41 and the introduction and discharge of the oxidant 42 may be repeated depending on the thickness necessary for the insulating film 32. The film thickness can be increased depending on the number of repetitions. Accordingly, a desired film thickness can be easily obtained.

Thereafter, the particles 33 with the insulating films may be subjected to a posttreatment as necessary. Examples of the posttreatment include a destaticizing treatment and a radical treatment.

Among them, the destaticizing treatment is a treatment for reducing the amount of electric charge due to charging of the particles 33 with the insulating films. For example, an ionizer is used for the destaticizing treatment.

Examples of the constituent material of the insulating film 32 to be formed include oxides such as silicon oxide, hafnium oxide, tantalum oxide, titanium oxide, and chromium oxide, and nitrides such as aluminum nitride, titanium nitride, and tantalum nitride.

The thickness of the insulating film 32 is not particularly limited, and is, for example, preferably 1 nm or more and 500 nm or less, more preferably 2 nm or more and 300 nm or less, and still more preferably 4 nm or more and 200 nm or less. With such a film thickness, the film can be uniformly formed in a relatively short time. In addition, according to the chemical vapor deposition method, the dense insulating film 32 can be formed, and thus a sufficient insulation capability can be obtained even with such a small film thickness. Therefore, it is possible to obtain the particles 33 with insulating films, by which a pressure magnetic core or the like having excellent magnetic properties can be produced.

As described above, in the particle coating method according to the embodiment, in the arrangement step S1, the plurality of trays 12 on which the powder layers 30 of the metal particles 31 are formed are stacked at a gap G of 5 mm or more and 200 mm or less, and are accommodated and arranged. Therefore, the gas 41 and the oxidant 42 can easily enter the gap between the trays 12, and the insulating film 32 can be easily formed at a uniform film thickness. In addition, the plurality of trays 12 are stacked, and therefore, it is possible to efficiently produce the particles 33 with the insulating films while saving the space of the particle coating apparatus 1.

In the heating step S2, the powder layer 30 is heated in a temperature range of 100° C. or higher and 500° C. or lower for 0.1 hours or longer and 300 hours or shorter, and therefore, the crystallization of the amorphous phase can be prevented, and the strain contained in the metal particles 31 can be relaxed. Therefore, excellent low coercive force and low eddy current loss derived from the amorphous phase can be maintained, a further reduction in coercive force can be achieved along with the relaxation of strain, and the particles 33 with insulating films having a low coercive force and a high quality can be efficiently produced.

In the insulating film forming step S3, when the gas 41 or the oxidant 42 is introduced into the gap between the trays 12, the conductance between the trays 12 in an atmosphere at 20° C. is 20 m³/s to 2.0×10⁴ m³/s, and therefore, the gas 41 and the oxidant 42 easily enter the gap between the trays 12, and the insulating film 32 is easily formed at a more uniform film thickness.

What is claimed is:

1. A particle coating apparatus comprising:
a chamber having a volume of 10 L to 100 L;
a gas introduction unit provided at the chamber and configured to introduce a predetermined gas into the chamber;
a gas discharge unit provided at the chamber and configured to discharge the gas in the chamber;
a heating unit configured to heat an inside of the chamber;
a plurality of trays accommodated in the chamber and configured to hold metal particles to form a powder layer at a predetermined depth; and
a valve coupled to the gas introduction unit and a valve provided at the gas discharge unit, wherein
the plurality of trays are stacked at a gap of 5 mm or more and 200 mm or less, and a conductance between the trays in an atmosphere at 20° C. is 20 m³/s to 2.0×10⁴ m³/s.

2. The particle coating apparatus according to claim 1, wherein
when an average particle diameter of the metal particles is 0.5 μm to 10 μm, the tray has a depth of 5 mm or less.

3. The particle coating apparatus according to claim 1, wherein
when an average particle diameter of the metal particles is 10 μm to 100 μm, the tray has a depth of 10 mm or less.

4. The particle coating apparatus according to claim 1, wherein
an inner surface of the tray or an inner wall of the chamber has a surface roughness Ra of 0.1 or less.

5. The particle coating apparatus according to claim 1, wherein
a material of an inner surface of the tray or an inner wall of the chamber is gold or ruthenium.

6. The particle coating apparatus according to claim 1, wherein
an inner surface of the tray or an inner wall of the chamber is coated with fluorine.

7. A particle coating method comprising:
an arrangement step of stacking, at a gap of 5 mm or more and 200 mm or less, a plurality of trays configured to hold metal particles to form a powder layer at a predetermined depth and accommodating and arranging the plurality of trays in a chamber;
a heating step of heating the powder layer in a temperature range of 100° C. or higher and 500° C. or lower for 0.1 hours or longer and 300 hours or shorter; and
an insulating film forming step of forming an insulating film on surfaces of the metal particles by an atomic layer deposition method, wherein
in the insulating film forming step, a conductance between the trays in an atmosphere at 20° C. is 20 m³/s to 2.0×10⁴ m³/s.

8. The particle coating method according to claim 7, wherein
the metal particles having an average particle diameter of 0.5 μm to 10 μm are spread on the tray to form the powder layer at a depth of 5 mm or less.

9. The particle coating method according to claim 7, wherein
the metal particles having an average particle diameter of 10 μm to 100 μm are spread on the tray to form the powder layer at a depth of 10 mm or less.
